(19) United States
(12) Patent Application Publication
(10) Pub. No.: US 2025/0277844 A1
(43) Pub. Date: Sep. 4, 2025

(54) ARTIFICIAL INTELLIGENCE-ASSISTED CONSTRUCTION FOR TEST AND MEASUREMENT DEVICES AND ENVIRONMENTS

(71) Applicant: Tektronix, Inc., Beaverton, OR (US)

(72) Inventors: Keith D. Rule, Beaverton, OR (US); Frederick B. Kuhlman, III, Nashville, TN (US); Aaron Acton, Pittsburgh, PA (US); Alexander Ulyanov, Koeln (DE); Sean T. Marty, Beaverton, OR (US); Dane Miller, Salt Lake City, UT (US)

(21) Appl. No.: 18/825,274

(22) Filed: Sep. 5, 2024

Related U.S. Application Data
(60) Provisional application No. 63/559,390, filed on Feb. 29, 2024.

(51) Int. Cl. G01R 31/28; G06N 20/00

(52) U.S. Cl. CPC G01R 31/28; G06N 20/00

(57) ABSTRACT

A test and measurement system includes one or more test and measurement instruments comprising at least one test and measurement instrument having one or more ports to connect the to a device under test (DUT), one or more memories including test and measurement knowledge, a generative artificial intelligence (AI) model connected to the one or more test and measurement instruments, and the one or more memories, one or more processors to: present a user interface having a prompt to a user, receive a request from the user, the request comprising one or more tasks to be performed by the one or more test and measurement instrument, access an application programming interface (API) of the generative AI model to translate the request to commands, send the commands to the one or more test and measurement instruments, and display an output on the user interface.

### CROSS-REFERENCE TO RELATED APPLICATIONS

This disclosure is a non-provisional of and claims benefit from U.S. Provisional Application No. 63/559,390, titled “ARTIFICIAL INTELLIGENCE-ASSISTED CONSTRUCTION FOR TEST AND MEASUREMENT DEVICES AND ENVIRONMENTS,” filed on Feb. 29, 2024, the disclosure of which is incorporated herein by reference in its entirety.

### TECHNICAL FIELD

This disclosure relates to artificial intelligence assistance, and more particularly to artificial intelligence-assisted construction for test and measurement devices and environments.

### DESCRIPTION

There has been a lot of progress in the technology around artificial intelligence (AI) assistants. Technology has made AI assistants as applications feasible to create. OpenAI even has an app store of AI assistant extensions. As such, OpenAI has added extensions to their programming application programming interfaces (APIs) that allow for prompts and files to add to the knowledge of the assistant. OpenAI has added extensions to their programming APIs that allow for functions to allow the assistant to interact with local or web resources, which is a bidirectional connection and not only requests actions but expects responses. OpenAI has added extensions to their programming APIs that allow for files to extend the knowledge of the Assistant.

The key to making an AI assistant useful is providing abstractions and knowledge about the context the user is working in. This context is not likely something on which any existing large language models (LLMs) may have been trained.

In addition, some AI assistants are implemented as a REPL (Read/Evaluate/Print Loop). However, such implementation is not the only way to implement an AI assistant.

### BRIEF DESCRIPTION OF THE DRAWINGS

FIG. 1 shows a system diagram of an embodiment of a test and measurement system having an artificial intelligence (AI) assistant.

FIG. 2 shows an embodiment of a sequence diagram of an AI assistant start up and initial prompt.

FIG. 3 shows an embodiment of a test set up using a computing device having an AI assistant.

FIG. 4 shows a system diagram of an embodiment of a test and measurement system having multiple instruments and an AI assistant.

FIG. 5 shows an embodiment of a user response to a prompt from the AI assistant and the AI system response on a test and measurement device user interface.

FIG. 6 shows a user interface having voice control of an AI assistant.

FIG. 7 shows a user interface instructing an AI assistant to make measurements.

FIG. 8 shows a user interface having a split display showing a resulting waveform and a Fast Fourier Transform (FFT) as a result of an instruction to an AI assistant.

FIG. 9 shows a user interface on a test and measurement instrument after instructing an AI assistant to perform an operation with the instrument on a different channel.

FIG. 10 shows a user interface on a test and measurement instrument after a request and a response from an AI assistant.

FIG. 11 shows a result after a decode operation using an AI assistant.

FIGS. 12-13 shows user interfaces on a test instrument after receiving a voice prompt in another language.

FIG. 14 shows a user interface on a test and measurement instrument after receiving a request to save a screen shot.

FIG. 15 shows an embodiment of a waveform on a sampling oscilloscope.

FIGS. 16-22 show a user interface through series of interactions with an AI assistant to make a measurement using primitives and save the measurement.

FIGS. 23 and 24 show a user interface for extending waveform selections and measurements to a different waveform.

### DETAILED DESCRIPTION

The embodiments herein relate to methods to build an artificial intelligence (AI) assistant focused on test and measurement (T&M) devices. The embodiments also relate to methods to present the dynamic environment of a test environment using test and measurement equipment to an AI assistant so that a user can engage with the AI assistant at a high level.

Though this disclosure discusses specifics of the OpenAI API (application programming interface) and technology, the general features discussed herein apply to current and emerging Assistant APIs. This disclosure does not target OpenAI and its APIs specifically. Other AI tools exist and have APIs available to access them including, but not limited to AlphaCode, GitHub/Microsoft Copilot, Duet AI, and Bard, among many others.

Currently, General Pre-trained Transforms (GPTs) and large language models (LLMs) and the associated tools for them run on the Cloud, on the Edge, or even in the firmware of a T&M instrument. Storing the information in the firmware balances security by keeping all communication local, and using the Cloud increases performance by allowing computation scaling for faster or more accurate results. In addition, the examples in the discussion below focus on the use of current GPTs/LLM technologies, which may include smaller embedded LLMs in addition to the larger, more well known LLMs. However, other tools like Natural Language Processing (NLP) libraries along with other forms of machine learning can create similar behavior. While the examples in the below discussion are specific to GPTs/LLMs, no limitation to these particular technologies is intended nor should any be inferred. The embodiments here may apply to many different types of present and future generative AI technologies.

Similarly, for ease of discussion and understanding, the below discussion uses this example of an AI assistant for an oscilloscope with the understanding that no limitation to this type of equipment is intended nor should any be inferred. A broader set of instruments may include oscilloscopes, waveform generators, function generators, digital multimeters, source measurement units, spectrum analyzers, and switches, and is not limited to that set. Generally, the embodiments herein may apply to any set of controllable instrumentation usable together to understand a device or environment can be automated employing the assistant of the embodiments.

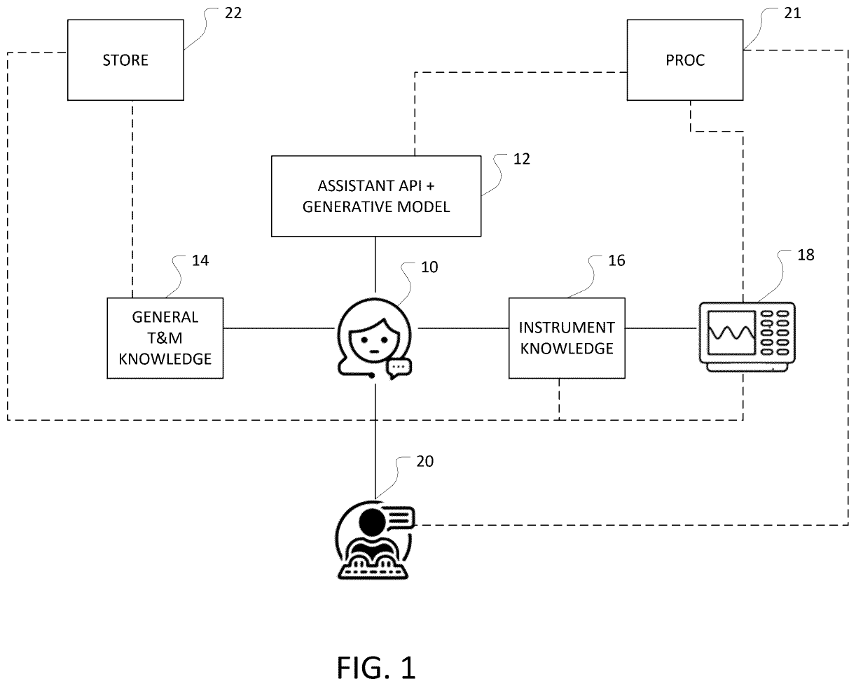

FIG. 1 shows the relationships between entities in an embodiment of an AI assistant 10 interacting with a single instrument 18 such as a scope, such as a Tektronix® MSO58B oscilloscope. The AI assistant 10 comprises a software program accessible by the user to allow the user to have simplified interactions with the test and measurement instrument such as instrument 18. The user launches the AI assistant 10 for use, but prior to launch, the AI assistant 10 needs to be configured. As part of the configuration, the AI assistant 10 receives general test and measurement knowledge 14. The term “receiving” may include the AI assistant 10 receiving a link to a repository or store of the knowledge that the AI assistant 10 can access as needed. The general test and measurement knowledge 14 may include testing procedures, parameters, and target values for many different standards, as well as overall information on different types of test and measurement instruments and their operation. As stated above, the instrument knowledge 16 contains information about the specific instrument 18, such as oscilloscopes, arbitrary wave, or function, generators, digital multimeters, source measurement units, among many other known test and measurement instruments.

As mentioned above, the test and measurement system shown in FIG. 1 has processing capability that executes code to both configure and operate the AI assistant 10. The processor(s) 21 may reside in instrument 18, the server or other cloud or edge device such as where the generative model 12 resides, or with a connected computing device that the user accesses. The dashed lines connecting the processor show the various locations where the processor(s) reside. The processing tasks may also be distributed across the system. Similarly, the general test and measurement knowledge 14 and the instrument knowledge 16 may reside in a common store 22, a separate store such as 16, or in the instrument 18 itself.

In an embodiment of a test and measurement system including an AI assistant system, the elements include an AI assistant API (application programming interface) and the generative model 12, general test and measurement knowledge 14, device specific instrument knowledge 16, the user 20, and the instrument 18. In such example, the AI assistant API 12 allows a programming language to interact with a generative AI model, such as a large language model (LLM) model. In some examples, the model comprises an LLM model possibly provided by a third party or created and fine-tuned by the user. In some examples, knowledge blocks 14 and 16 contain information that provides context to an AI assistant 10 but is not information that may likely have been pretrained in the model. Knowledge can include files such as specifications, or descriptions of an environment. Knowledge can also include sets of prompts with corresponding expected results. Knowledge block 14 may comprise a portion, such as a partition, of the store 22, and the instrument knowledge 16 may reside in a memory on the instrument 18. Alternatively, both knowledge blocks may reside in the store 22, which, similar to the AI model, may reside in the instrument, on the Cloud, or in an Edge.

In some examples, functions are a set of one or more actions from the instrument 18, usually backed by code. The description of the function, its arguments, and its return results are provided to the AI assistant 10. Functions are a way to provide dynamic knowledge, such as the state of the instruments, to the AI assistant 10 or for the AI assistant 10 to request an action to be performed. In some examples, the user 20 is the person or program that requests information or actions using a prompt. In some examples, the instrument 18 is an oscilloscope, such as the MSO58B oscilloscope with eight channels. The AI assistant 10 can interact with the instrument 18 programmatically. In the example of the AI assistant 10 interacting with the instrument 18 programmatically, the scope is the target instrument for the dynamic knowledge, or actions requested by the AI assistant 10.

One or more instruments such as instrument 18 may be assigned to an AI assistant 10 at start-up. The assignment at startup may configure the AI assistant 10 to converse about the test and measurement environment the user has built, and with which the AI assistant 10 is interacting.

In some examples, when describing functions to the AI assistant 10, the user 20 can define the following: function name, what the function does, what the function returns, and definitions for each of the input arguments of the function. In the examples below, the above information is extracted using a function decorator by the user 20. In one embodiment, the function decorator creates the appropriate JavaScript Object Notation (JSON) for the AI assistant 10. JSON as used herein means a language-independent text format, despite it seeming to only apply to Java. The JSON contains the function name, the doc string description which defines what the function does and what the function returns, and the argument descriptions. The embodiments are not limited to the particular implementation using JSON. Other implementations may include vector databases and template libraries. The actual mechanism used depends on the language the AI assistant 10 is implemented in and the specifics of the underlying AI assistant API 12.

There are several scenarios where functions are useful in test and measurement environments. Below are examples of Python code showing examples of determining instrument capabilities, performing actions, querying the instrument, and the data returned.

| | |
|---|---|
| 1. | Determining Instrument Capabilities |
| | @openai_function( ) |
| | def get_scopt_channel_count(scope) |
| | “”” |
| | Return the number of channels available in the scope. Scopes typically have 2, 4, or 8 |
| | channels depending upon the model. |
| | This call must be made to know the correct number of channels since the channel count is |
| | not the same for all scopes. |
| | “”” |
| | if connect: |
| | idn = scope.query(‘*IDN?’) |
| | fields = idn.split(‘,’) |
| | if (fields[1] == ‘MSO58’ or fields[1] == ’MSO58B’): |
| | return “8” |
| | elif(fields[1]]== ‘MSO56’ or fields[1] == ‘MSO56B’): |
| | return “6” |
| | elif (fields[1] == ‘MSO54’ or fields[1] == ’MSO54B’): |
| | return “4” |
| | elif(fields[1]]== ‘MSO66’ of fields[1] == ‘MSO66B’): |
| | return “6” |
| | elif(fields[1]]== ‘MSO64’ of fields[1] == ‘MSO64B’): |
| | return “4” |
| | return “8” |
| 2. | Performing Actions |
| | @openai_function(state=”State to set awg output to, Options are ON or OFF. If not |
| | specified, then use ON”) |
| | def set_awg_state(scope,state = “ON”): |
| | “”” |
| | This is a function that is used to set output state of the awg. The state is either ON or |
| | OFF. |
| | “”” |
| | try: |
| | if connect: |
| | scope.write(f”:AFG:OUTPut:State {state}”) |
| | outilfe.write(f”scope.write(‘:AFG:OUTPut:State {state}’)\n”) |
| | if verbose: |
| | print(f”set_awg_state({state}) - Success”) |
| | return f”Success” |
| | except Exception as e: |
| | print(f”set_awg_state({state}) - Failed:” + str(e)) |
| | return “Failed: “+ str(e) |
| 3. | Querying State |

@openai_function(channel=”The channel to return the state. Channel may be CH1, CH2, CH3,
Ch4, CH5, CH6, CH7, or CH* depending upon the number of channels in the scope”)
def get_scope_channel_state (scope, channel):
“””

Get the scope channel state. The value returned is either ON or OFF.

“””

```
try:
  if connect:
    return scope.query(f”:SELECT:{channel}?”)
  return “OFF”
except:
  return f”Failed: {e}”
```

After execution of the above code, the system returns the related data.

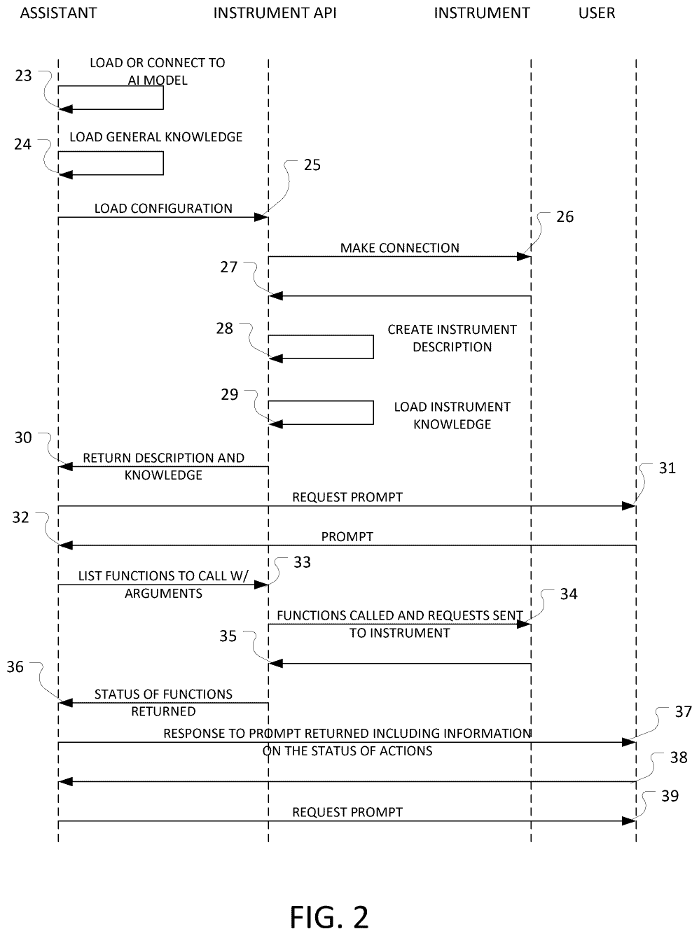

FIG. 2 shows a sequence diagram for the startup of the test and measurement AI assistant described in FIG. 1. In the diagram of FIG. 2, the various elements of the system interact with the AI Assistant, including the instrument API, the instrument, and the user. When the AI assistant launches, it undergoes configuration by loading or connecting the generative AI model at 23, sometimes referred to as the AI model. As discussed above, the AI assistant may use a ‘local’ copy of the AI model or a ‘remote’ copy of the model that resides in the cloud or on an edge device. The AI assistance loads or links to the general knowledge at 24, and the AI assistant loads the assistant's configuration to the instrument API at 25. The AI assistant then connects through the instrument API to the instrument at 26 and receives a response from the instrument at 27. The instrument, using its API, creates an instrument description at 28, and loads instrument knowledge at 29. The instrument then returns the instrument description and the instrument knowledge to the AI assistant at 30. At this point, the AI assistant has completed its configuration and notifies the user that the AI assistant awaits a prompt from the user at 31.

The user inputs the desired actions the user wants performed with the instrument on the device(s) under test (DUT). The AI assistant then converts the desired actions into the function calls and arguments, transparent to the user and sends them to the instrument API at 32. The function calls and arguments then reach the instrument at 34, and the instrument returns the status of functions returned and any other information at 35 to the instrument API, which in turns sends the status of functions returned and information at 36. The AI assistant then sends the response and the desired information back to the user at 37. The user then may indicate reception at 38, and the interaction may continue with further prompts at 39.

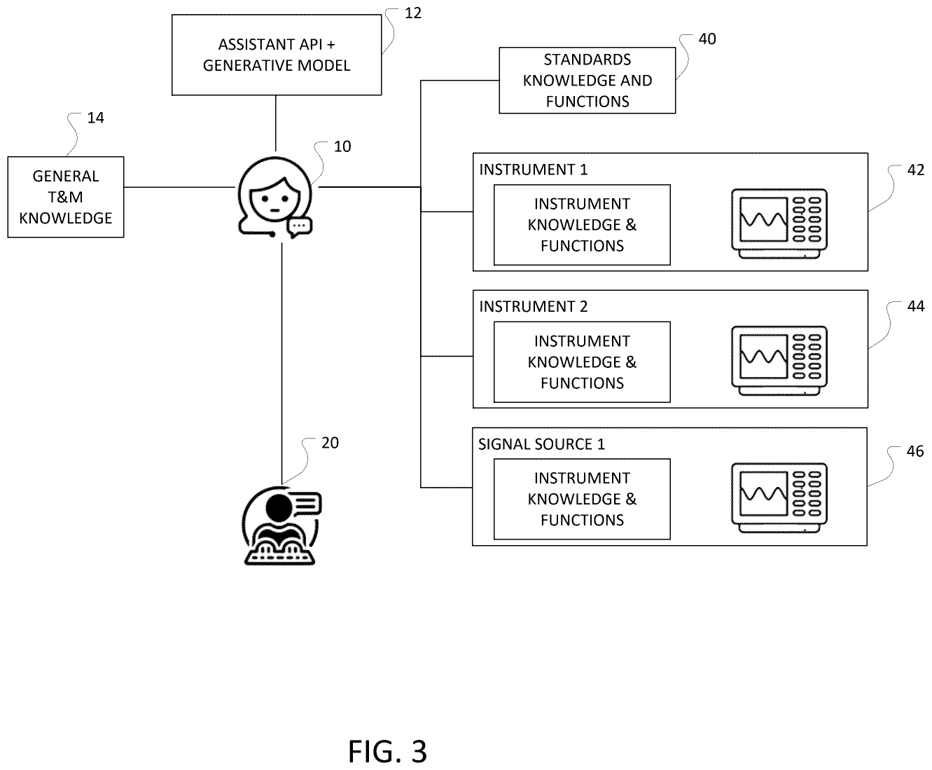

In some examples, users' setups are more complicated than just a single instrument. The example of FIG. 3 may have three instruments, or example, two instruments 42 and 44, and a signal source such as a waveform generator 46. The AI assistant 10 can be configured at startup to be aware of multiple devices and intended usage. Such configuration of the AI assistant 10 allows the user interaction to be at a higher level. Each instance of an instrument and a standard comprises a package, and the AI assistant 10 may manage this package in configuring and loading the package into the test and instrument system.

The three instruments 42, 44, and 46 in FIG. 3 each present themselves separately to AI assistant 10. In addition, since the setup of FIG. 3 is part of a specific type of test environment, the AI assistant 10 can be configured with additional knowledge and specifics for the specific type of test environment as part of either the general test and measurement knowledge 14, the instrument specific knowledge of one of the instruments, or as a separate store such as a portion, or partition. of the central store 40. The additional knowledge and specifics in store 30 provide the AI assistant 10 with enough knowledge that the user 20 can not only talk about the instruments 42, 44, and 46, but also about aspects of the overall environment. Store 40 and store 22 from FIG. 1 may reside as one unified memory, or may comprise separate memories, and either or both may reside in the Cloud, on the Edge, or in the test and measurement instrument.

One advantage of using such an approach lies in the ability of the assistant to take any standardized functions and knowledge provided for a type of instrument, such as an oscilloscope, even across different models or manufacturers' instrumentation, still working with the AI assistant. Another advantage of making requests at a higher level is that the AI assistant is naturally instrument-agnostic. Accordingly, the same prompts with different instruments generally produce similar results provided the substituted instruments were of similar or better capabilities.

There is no reason to interact with an AI assistant only through text or voice. Another approach could present programmatic access to the configured environment. Programmatic access to the configured environment allows for higher-level interaction with the instrument programmatically. For example, for a prompt of “Turn on channel 2, set the trigger source to this channel, and turn off all unused channels”, a user might turn that into code that looks like this:

Import pyvisa as visa
rm = visa.ResourceManager( )
scope = rem.open_resource(“GPIB0::1::INSTR”)
scope.write(“SELECT:CH1 OFF”) # turn off channel 1
scope.write(“SELECT.CH2 ON”) #turn on channel 2
scope.write(“SELECT.CH3 OFF”) #turn off channel 3
scope.write(“SELECT.CH4 OFF”) #turn off channel 4
scope.write(“TRIGGER:A:EDGE:SOURCE CH2”) # set the trigger source
to channel 2

The above code is one way to interact with an oscilloscope programmatically. The code targets a specific make and model. If a different make or model instrument were placed in this environment, the code may be rewritten.

Interacting with the AI assistant can change to the following instrument-agnostic code.

```
import tek_assistant
with tek_assistant.TekAssistant( ) as tek:
  tek.read_configuration( )
  tek.request(‘Turn on channel 2, set the trigger source to this channel,
and turn off all unused channels.’)
```

Another advantage in using the AI assistant lies in the AI assistant's ability to respond to requests that include no specific knowledge of the APIs provided by the scope. The user can say what the user wants, and the AI assistant performs the corresponding actions. The AI assistant is instrument-make/model agnostic. The AI assistant also makes comprehension of the intent of the test easier for users reviewing test results. The users no longer must reverse engineer the intent by reviewing code that maps intent to actions. While the above example uses Python, it may be implemented in many other ways, such as Representational State Transfer (REST).

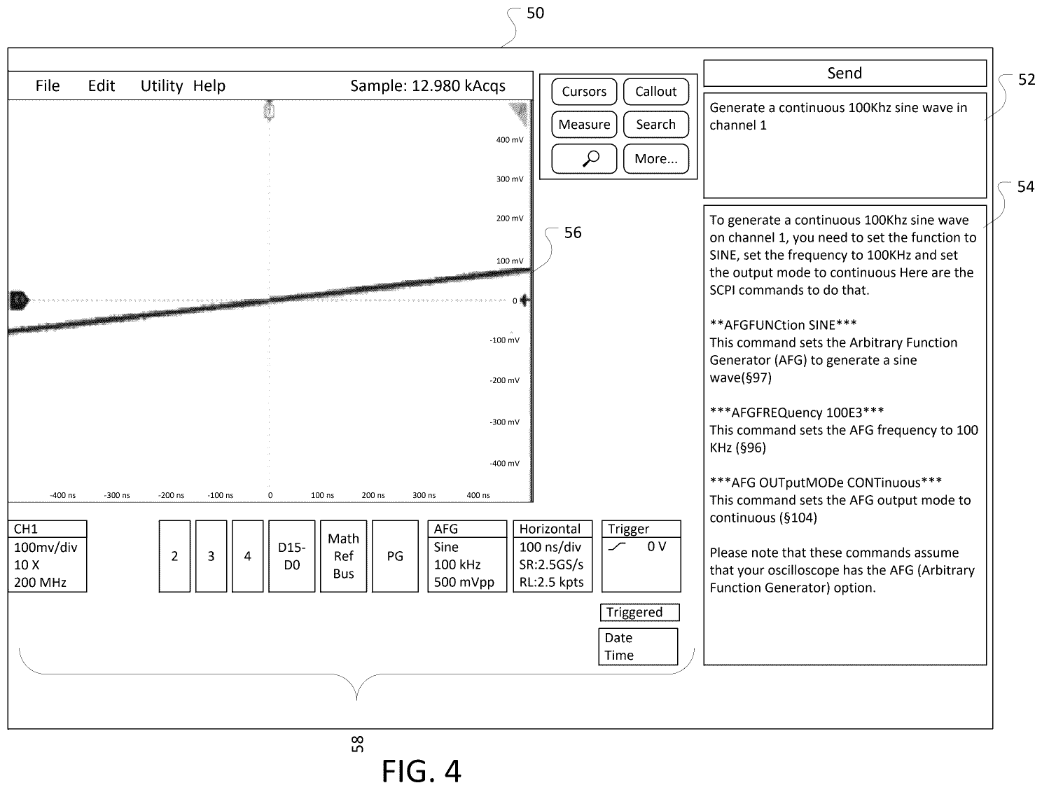

FIG. 4 shows an example of an oscilloscope user interface 50. The prompt window 52 shows an example user prompt to the AI assistant. The response window 54 shows the response from the AI assistant, and the resulting waveform in waveform window 56. As can be seen in the response window 44, the AI assistant of these embodiments lays out the way the user could perform the tasks themselves.

For simplification, the following figures will not show all of the various controls and other elements of the user interface, such as those shown in area 58, other than the waveform window and the prompt and response windows. The absence of the elements of the user interface should not be taken to mean that these components do not exist in the further figures. Some may be included if relevant to the discussion.

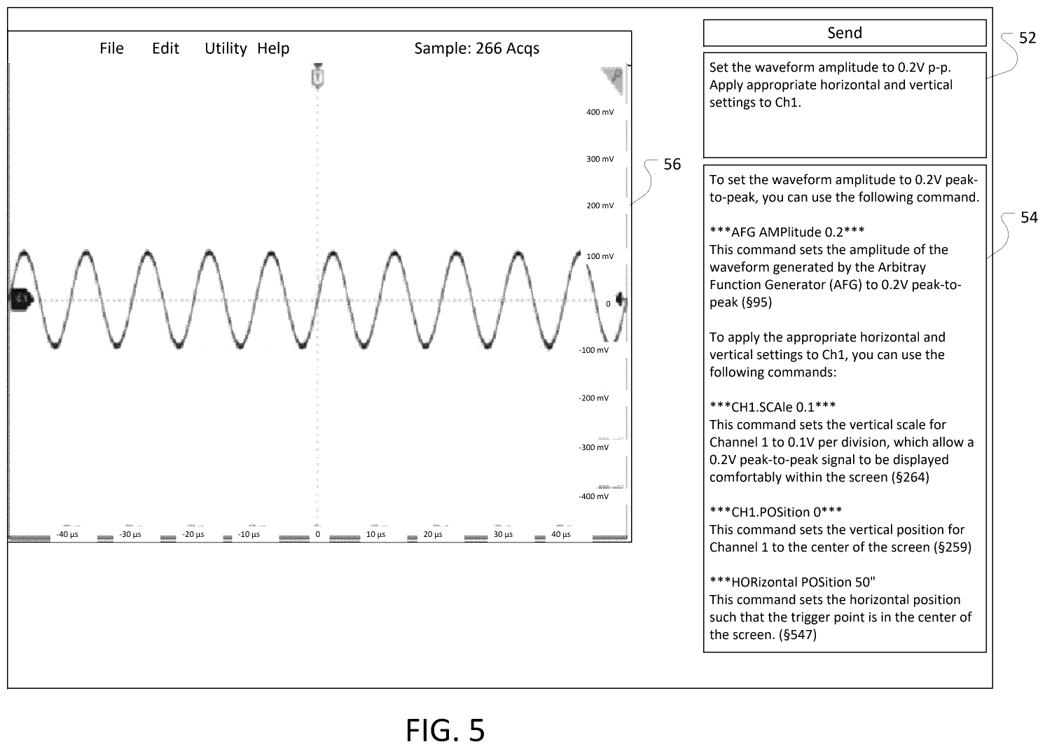

FIGS. 5-14 demonstrate the flexibility of an AI assistant. These are not intended to be exhaustive, and no limitation to these particular examples is intended nor should any be inferred.

FIG. 5 shows the result of a further interaction between the user and the AI assistant. The user wants to change the scaling of the signal FIG. 4. In the prompt window 52, the user changes the parameters of the waveform, and the assistant responds in window 54. The resulting change shows up in waveform window 56.

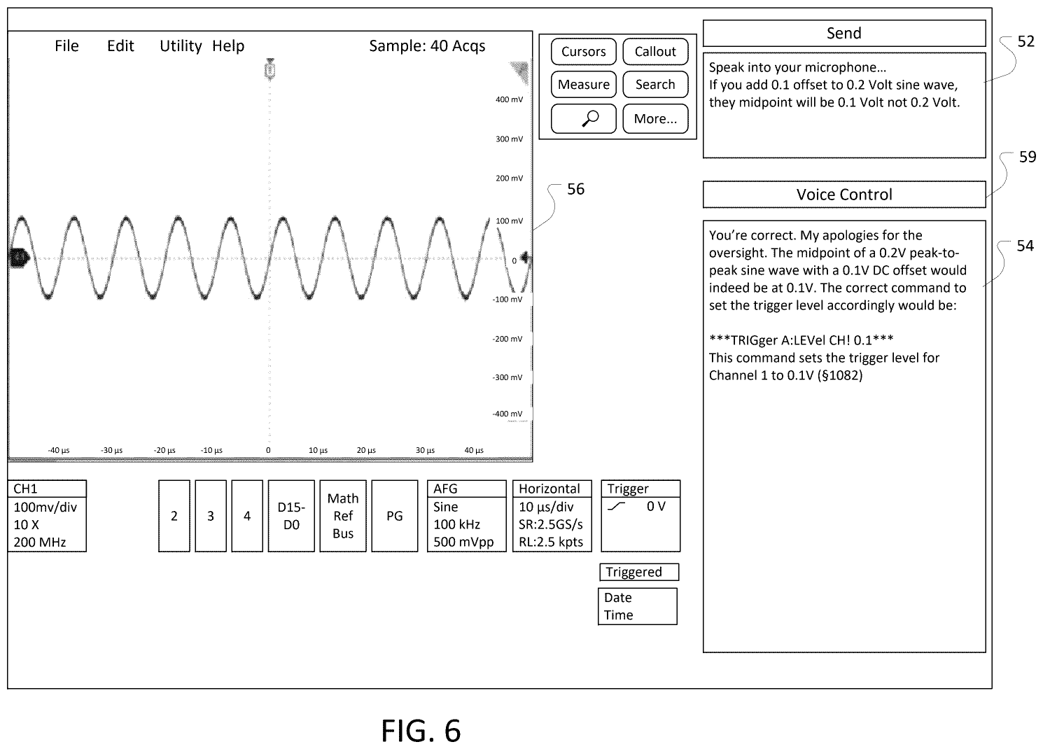

FIG. 6 shows a prompt that the assistant receives through a voice interface. The text of the box 59 shows “Voice Control.” In addition, the user had previously requested that a 0.1V offset be added to the sine wave shown in waveform window 56. The user, through the voice interface, states the offset was incorrect. The assistant apologizes and provides more details in the response window 54.

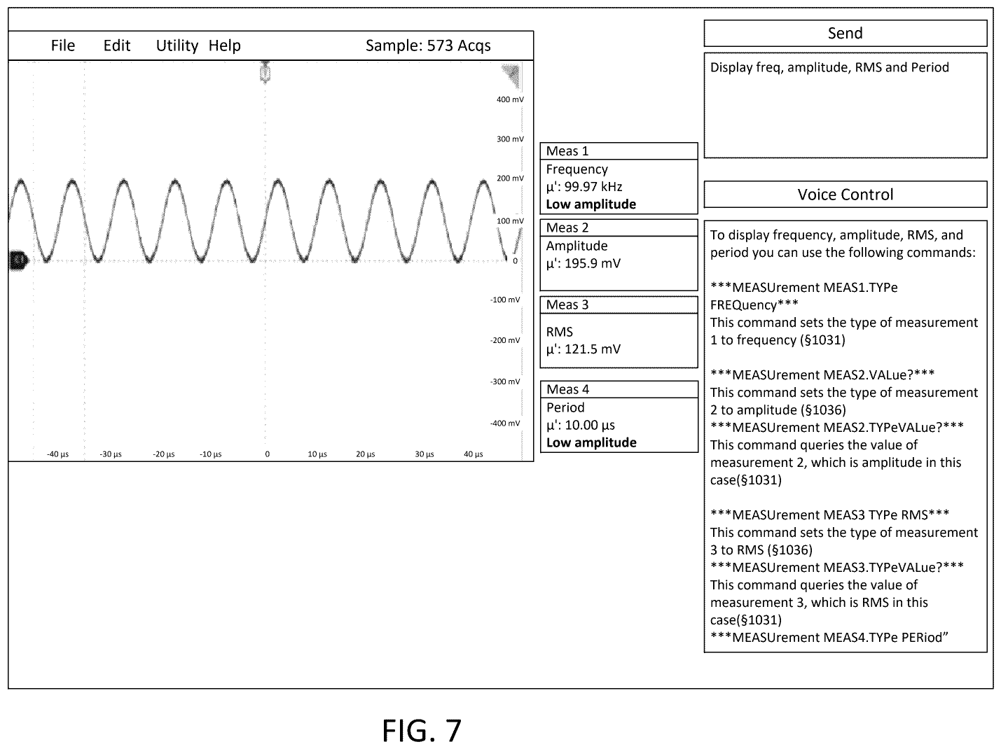

FIG. 7 shows the result of a prompt requesting measurements, with the results displayed in the middle of the user interface.

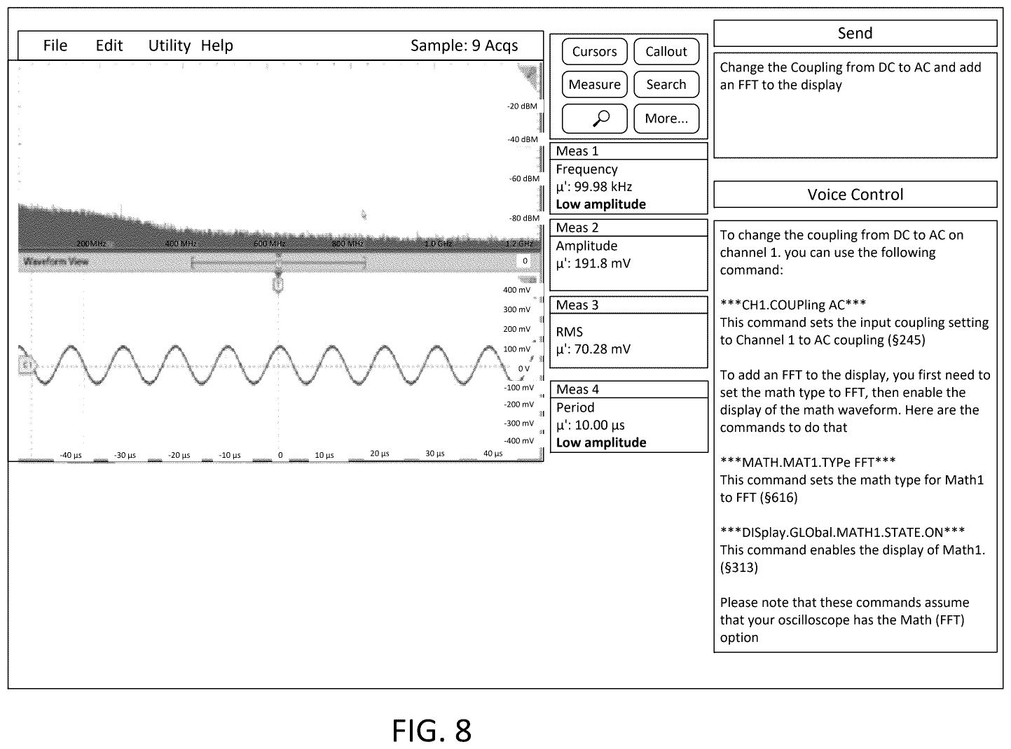

FIG. 8 demonstrates that the AI assistant can display other items than just waveforms, such as a Fast Fourier Transform (FFT).

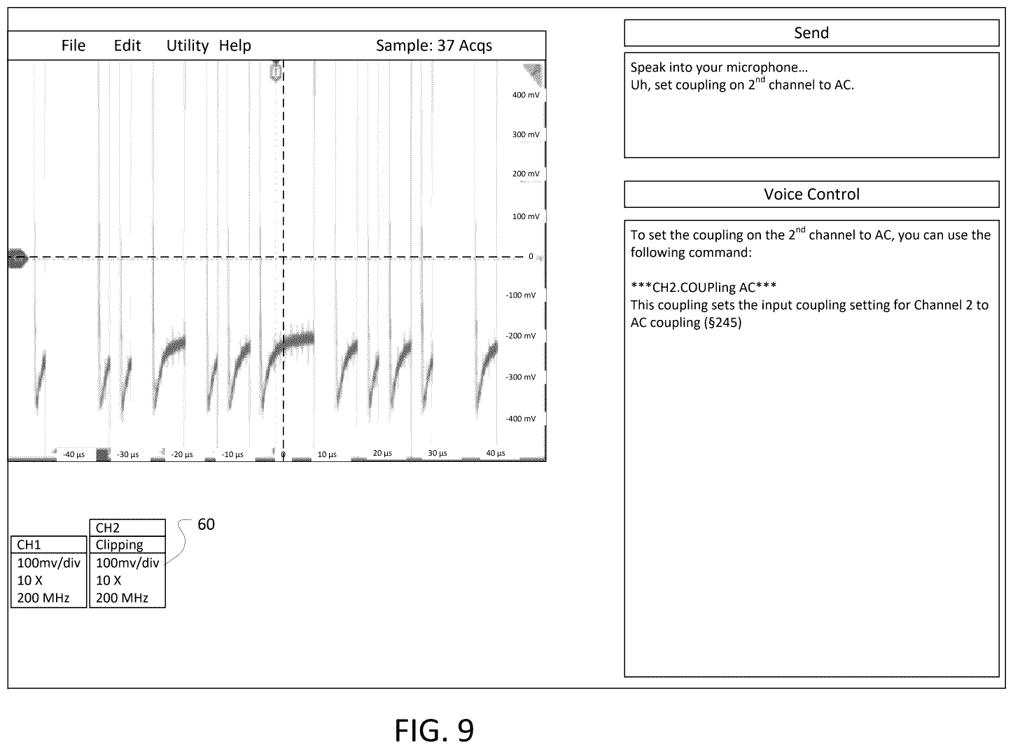

Prior to the image in FIG. 9, the user had asked the AI assistant to change the channel being displayed to Channel 2. This can be seen by box 60 at the lower left. In FIG. 9, the user has returned to using the voice control and the instrument is operating on channel 2.

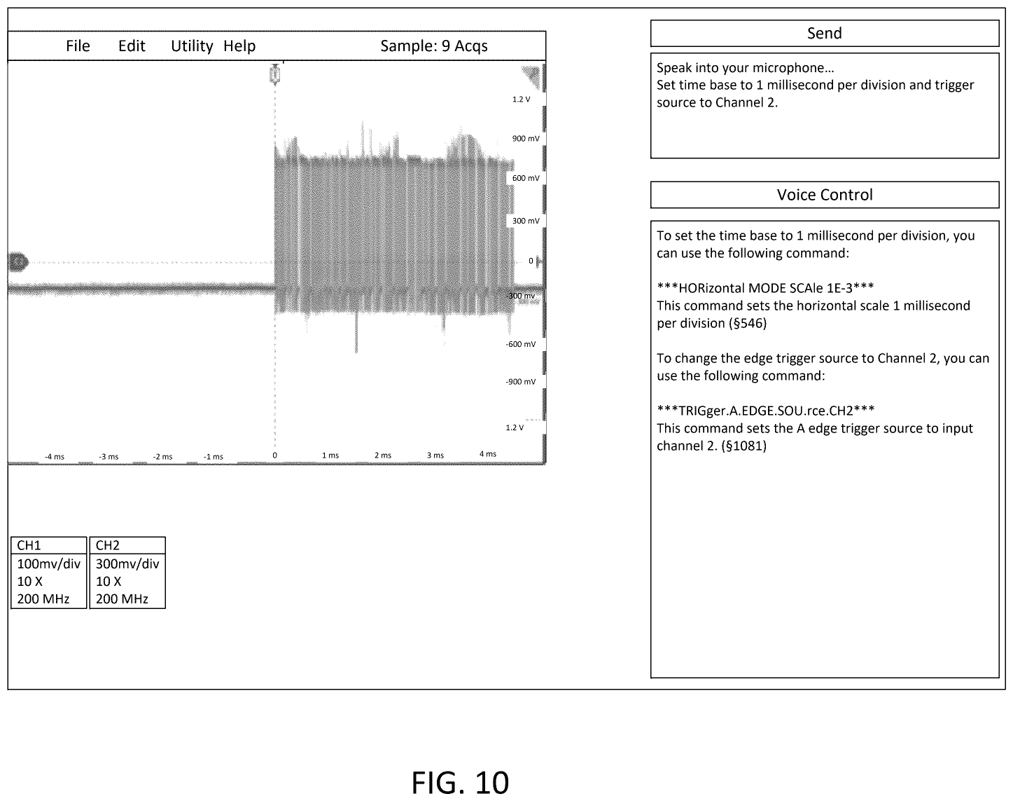

In FIG. 10, the user requested the scope to change the time base, and to have the scope trigger of channel 2, with the resulting waveform shown.

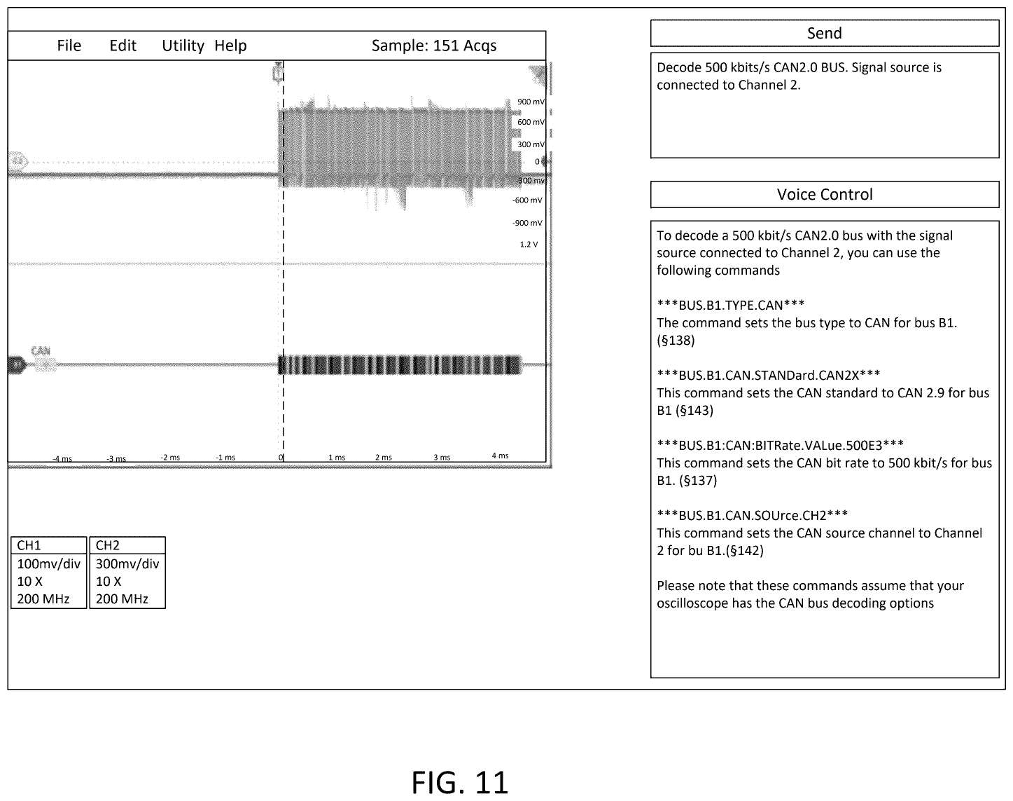

In FIG. 11, the user has requested that the signal be decoded as a controller area network (CAN) bus 2.0. The scope shows the results as a second display at the bottom of the waveform window.

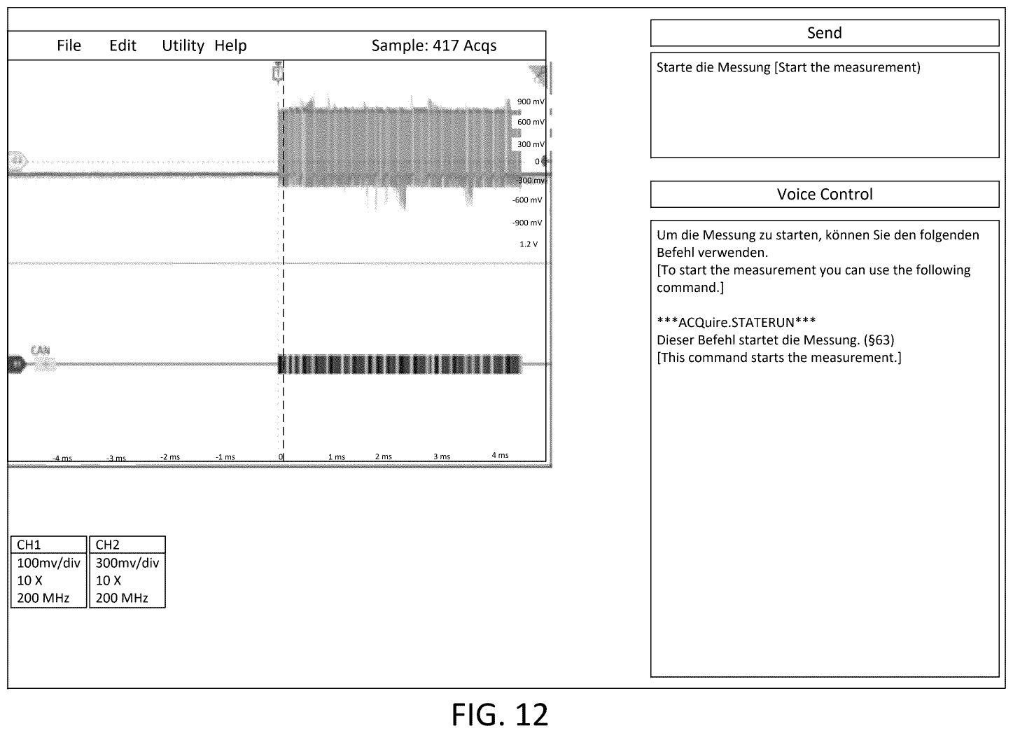

FIG. 12 shows another adaptation of the AI assistant. As can be seen in the prompt window, the user has made a request in German. The English translation has been added in brackets, it is not part of the display. The AI assistant interprets the German, performs the action, and responds in German.

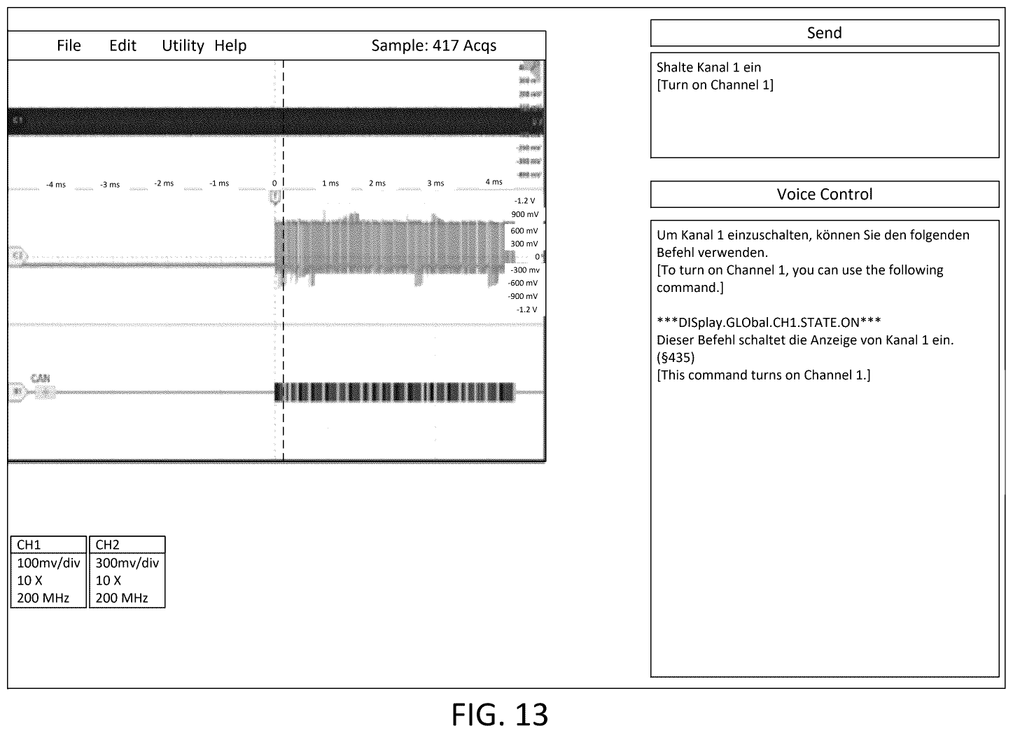

FIG. 13 shows another instance of the AI assistant responding in the language of the user and turning on a different channel in the scope.

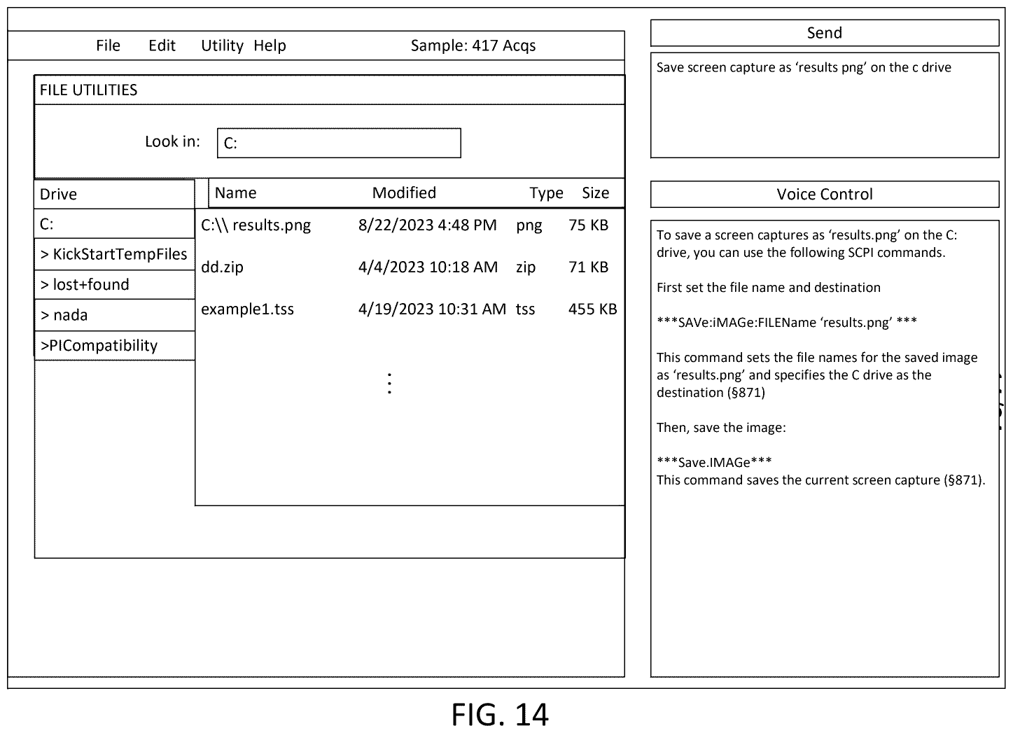

The AI assistant can also perform operations external to the instrument. In the user interface of FIG. 14, the user has requested that the screenshot of the user interface be saved to disk C: of an attached computing device. The above interfaces demonstrate the flexibility of using the AI assistant directly.

Currently, the process of using AI assistants can be slow. The speed of the AI assistants is partially because of the computing resources to return responses but also because some current LLMs are cloud-based, and the AI assistants share resources with thousands of other requests.

In one optimization, the AI assistant can record the actions needed to perform a specified prompt for a given system configuration. The assistant can then cache the results. Then, if the user employs the prompt in the same context, the actions taken and saved can be repeated, without involving the AI assistant.

This approach may be analogous to the just-in-time (JIT) compiling step that environments such as Java Virtual Machine (JVM) or .Net use to increase performance. The caching approach also means that for a given configuration, the saved actions for prompts May persist across runs so that the user converts prompts to actions once. Accordingly, subsequent runs may be as fast as the equivalent, human-coded automation script.

Not every test environment is the same. In some examples, the AI assistant may be able to infer the configuration based on the instruments connected to the workstation running the AI assistant. However, if the user wants to interact with an AI assistant that is aware of the context of the test environment, some startup configuration may be needed.

A configuration may look like this.

config:
name: “PCIe Gen3 x2”
scope:
- name: “Scope1”
- make: “Tektronix”
- model: “MDO58B”
- connection: “TCPIP::192.168.1.19::INSTR”
scope:
- name: “Scope2”
- make: “Tektronix”
- model: “MDO58B”
- connection: “TCPIP::192.168.1.23::INSTR”
generator:
- name: “Generator1”
- make: “Tektronix”
- model: “AWG5208”
- connection: “TCPIP::192.168.1.25::INSTR”

An alternative configuration using a different set of instruments may look like this:

config:
name: “PCIe Gen3 x2”
description: “PCIeGen3 x2 Test Setup for Compliance Testing”
scope:
- name: “Scope1”
- make: “Tektronix”
- model: “MDO66B”
- connection: “TCPIP::192.168.1.39::INSTR”
scope:
- name: “Scope2”
- make: “Tektronix”
- model: “DPO77002SX”
- connection: “TCPIP::192.168.1.42::INSTR”
generator:
- name: “Generator1”
- make: “Tektronix”
- model: “AWG5208”
connection: “TCPIP::192.168.1.25::INSTR”

By using a configuration as shown above, the AI assistant can look up the instrument's knowledge and function description from an existing library using Make and Model information. The connection string tells the underlying instrument API how to connect to that instrument for direct interaction using the instrument specific information. Each instance of an instrument is referred to by the provided name when interacting with the AI assistant. This information allows the AI assistant to interact with the instrument directly, rather than inferring the test configuration.

Having a set of predefined instrument knowledge and function definitions allows the AI assistant to interact with a large range of equipment types and for the usage to be instrument agnostic. Having a set of predefined instrument knowledge and function definitions may be analogous to standardized instrument drivers in existing automation environments.

AI assistants in the test and measurement domain are not limited to setting up and sequencing tests and presenting results. An AI assistant can be created to create a new bespoke analysis algorithm from a description. For example, the text below shows example measurement specifications from the DisplayPort 1.2 Specification from the Video Electronics Standards Association (VESA).
3.2.4 Measurement Requirements
The following requirements shall be met for each level measurement:
Number of Edges measured: >1000
Amplitude measurement will be performed using Vₛ=MAX(V_{H}, V_{L}) where V_{H} and V_{L} have the following definitions:
V_{H} is the Mode of the High or ‘one’ voltage over the last two UIs when three or more successive ones are transmitted.
V_{L} is the Mode of the Low or ‘zero’ voltage over the last two UIs when three or more successive 0's are transmitted.

$$Voltage Peak - Peak = {V}_{H} - {V}_{L}$$

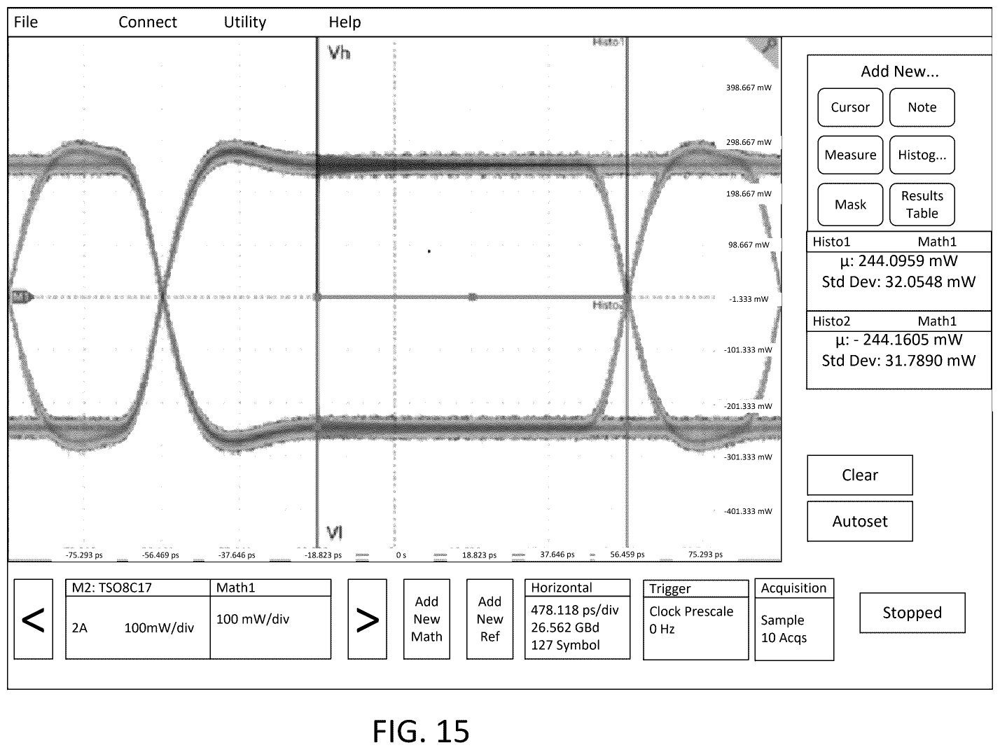

FIG. 15 shows an example of the above measurement loading into a sampling scope.

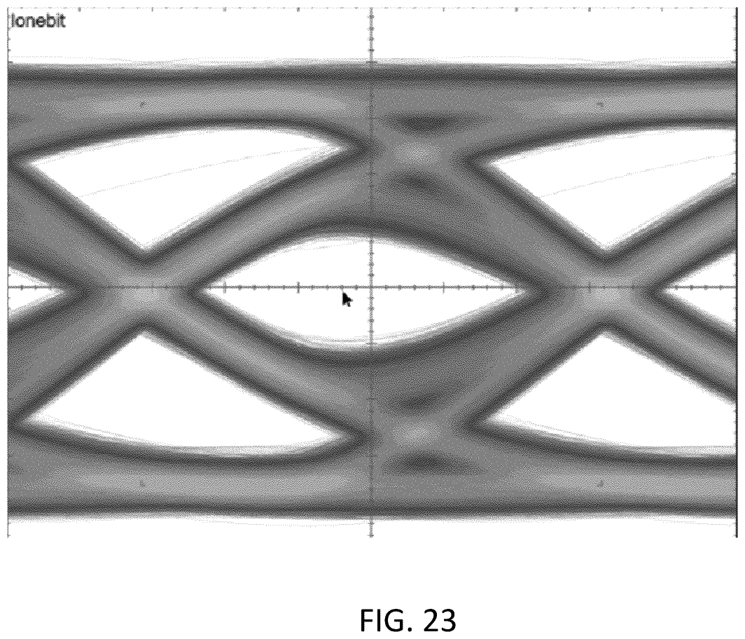

Converting the intent, such as the text describing the measurement, to a new measurement shown later in FIG. 23 can be done by providing the AI assistant with the correct knowledge and functions. However, the abstractions present may be close to types of request a user may make. As such, a set of primitives may be presented by the scope and its functions. As used herein, the term “primitive” means a declarative statement, sometimes referred to as built in behavior, but extensible.

The primitives to compose a series of scope features into a measurement are relatively small. Primitives include pattern matching a sequence of patterns or symbols, which creates a set of time ranges. Primitives include supporting Waveform DBs in Math expressions, which includes persistence across acquisitions. Primitives include overlaying the samples in the time ranges into a waveform database. Primitives include mapping the time on the screen to unit intervals and vertical values to normalized values related to Nominal 1 and 0 (for NRZ), and Levels 0-3 (PAM4). Primitives include allowing multiple named horizontal or vertical histograms using the UI or Normalized coordinates. Primitives include custom measurement expressions, such as Meas1=Hist1−Hist2. Primitives include storing and recalling the operations defined for a Math or Measurement as a newly named measurement. The above primitives are only intended as examples as users will probably want more primitives. The embodiments here allow more primitives to be added as desired or needed.

Given a small set of primitives such as this, an AI assistant can be configured to turn the test specification above into a reusable custom measurement. Primitives are similar to behaviors that can be composed in a small script. The AI assistant creates that small script without the user having to do so, and that script can be saved.

These same primitives could be included as part of the reusable analysis component. Using the same primitives allows this same assistant to define new measurements for any analysis component application. The definition can include custom user automation, automation tools, or instruments. In this way, the user can use the AI assistant to build re-usable, savable scripts. Future uses of the scripts may not require the AI assistant, which may present a more economically feasible option than using the AI assistant for each instance.

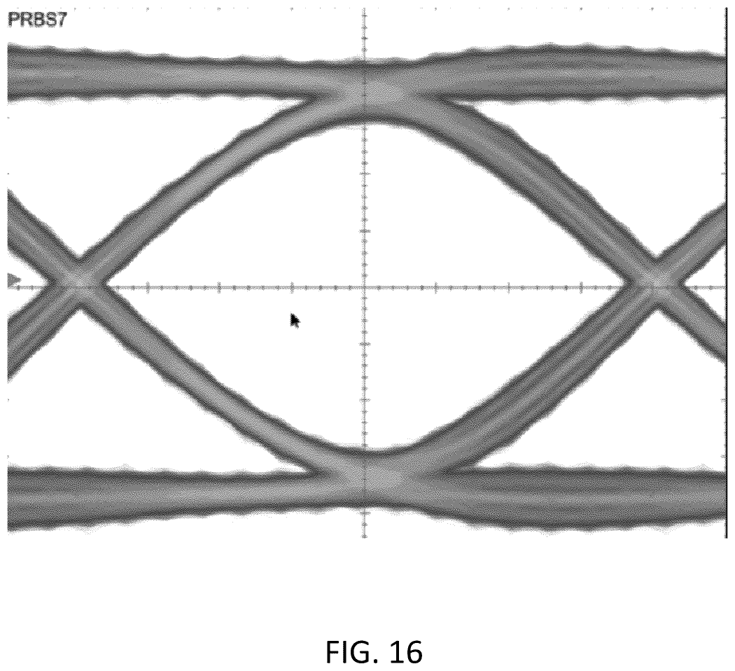

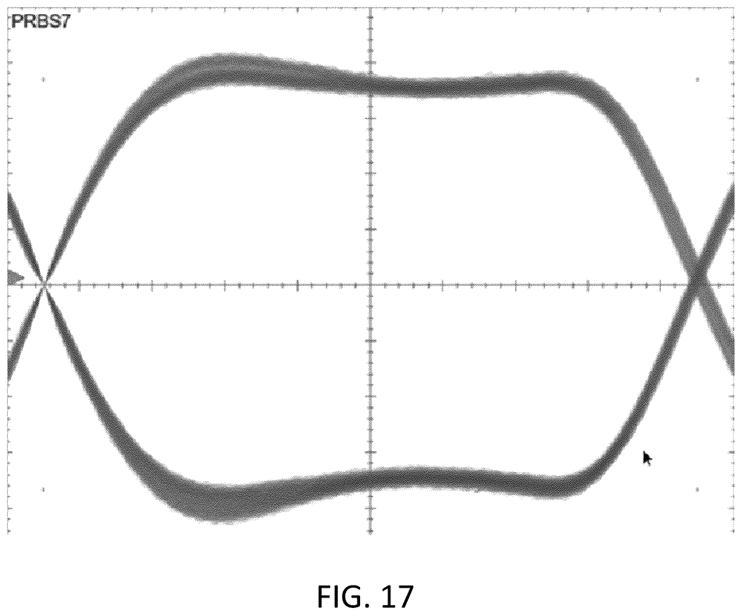

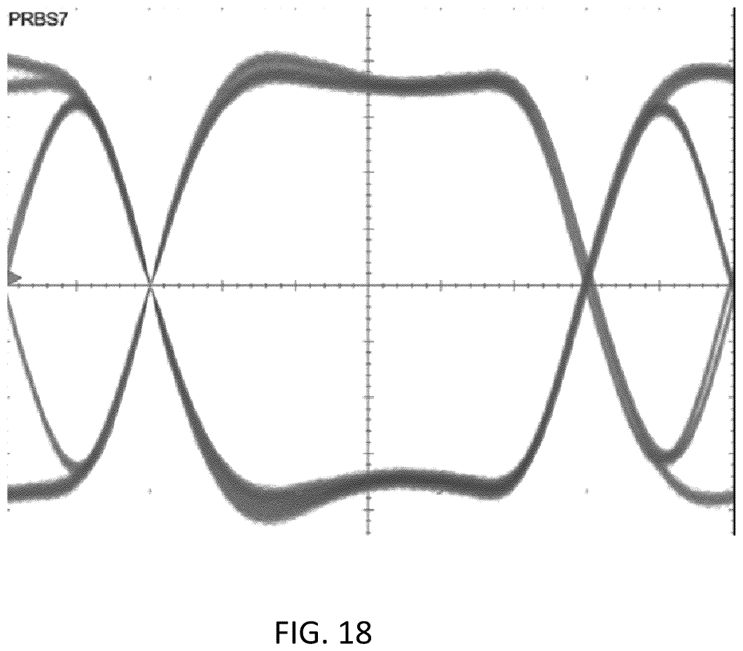

FIGS. 16-24 show examples for primitives. FIG. 16 shows a vector waveform that is folding. FIGS. 17 and 18 show the bit pattern and the inverse bit pattern of the waveform of FIG. 16 at different scales. In some cases, the measurements to be made may be statistical. For example, a user needs to look for a particular pattern to do a measurement. The exemplary measurement is of the amplitude of the bits once the bits settle after a transition bit. To do so, the user can use three non-transition bits followed by a transition bit. As shown, the waveform is folded and is shown in a coordinate system that is in unit intervals both horizontally and vertically. Accordingly, as shown, the waveform shows the location of the transition bits.

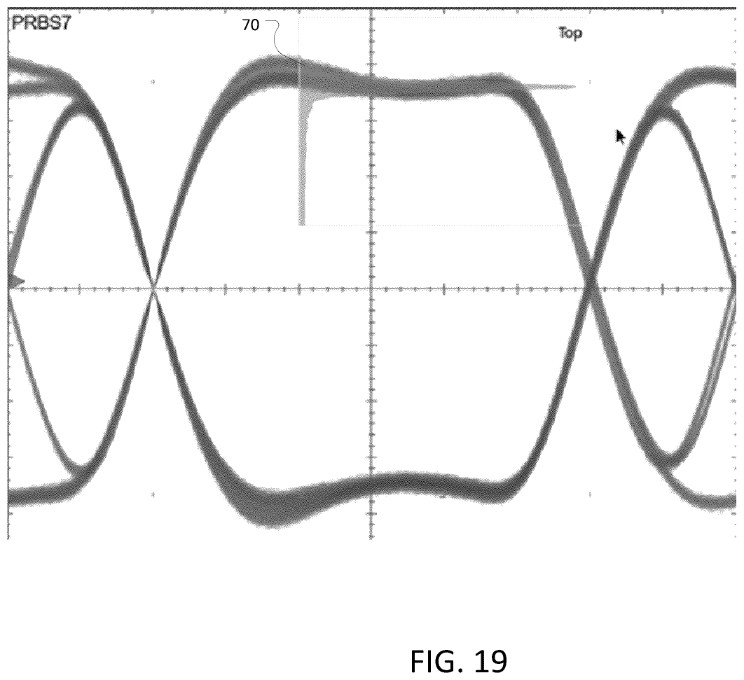

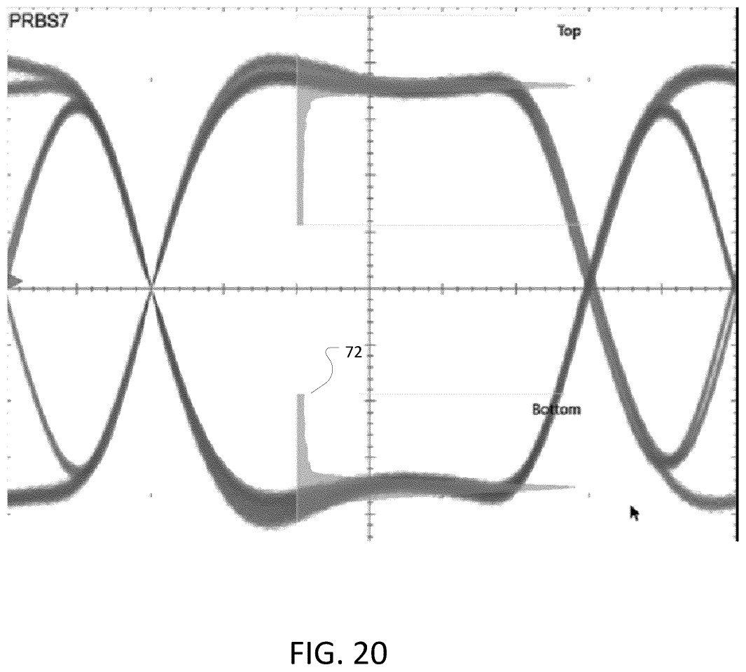

The measurement to be made is the amplitude of the waveform to the right of the transition bits. To do so includes using the histogram. FIG. 19 shows the selection of part of the waveform after the second transition bit to the non-transition bit for the histogram 70, and FIG. 20 shows the selection of another part of the waveform after the second transition bit to the non-transition bit for a histogram 72.

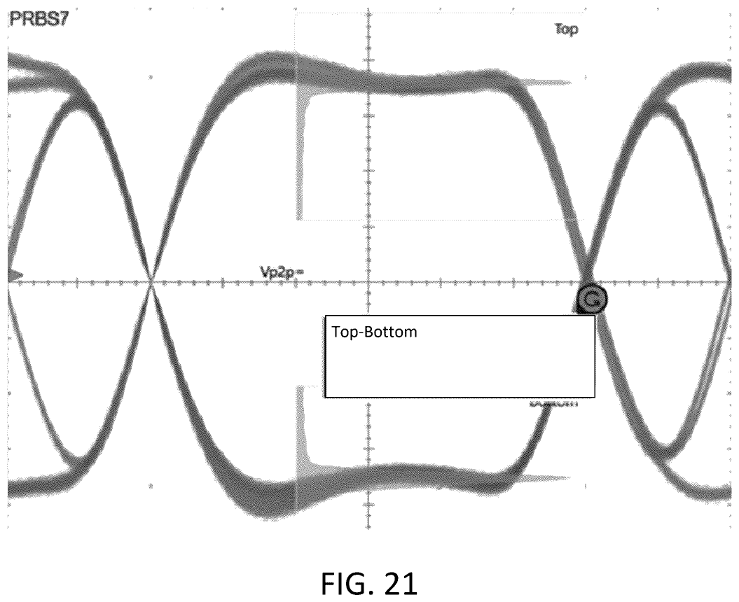

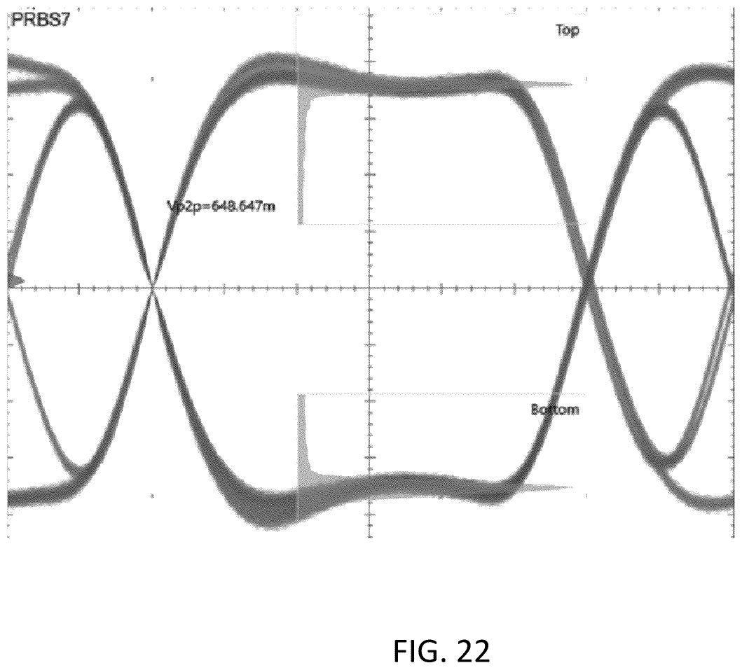

Afterwards, the user can include an equation to calculate the measurement. FIG. 21 show shows the inclusion of the equation of the top histogram and the bottom histogram to generate the measurement result, and FIG. 22 shows the result. As mentioned above, the user can save this equation derived from the user's requests converted to a script.

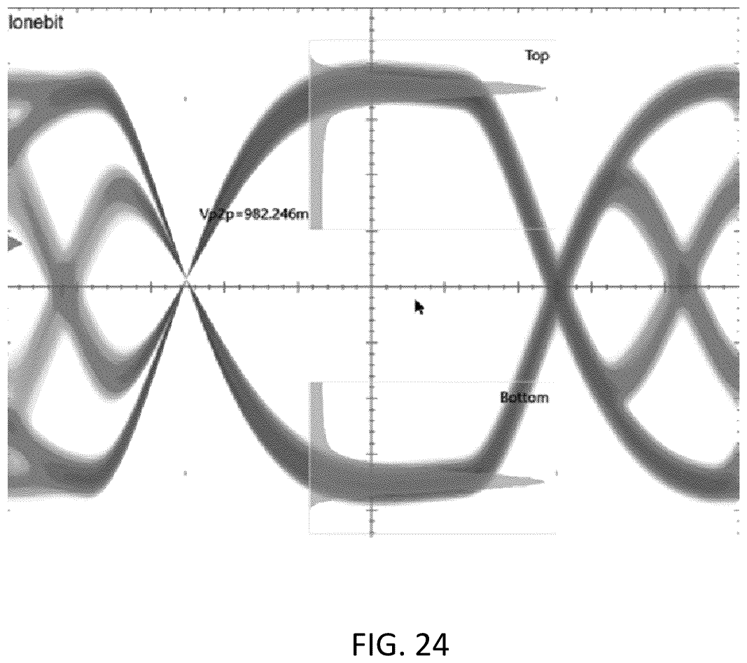

FIG. 23 shows a new waveform and FIG. 24 shows application of the script to the new waveform, demonstrating that the user can use the previously stored histogram calculation, the equation, and the result.

The AI assistant is not limited to setting up and sequencing steps, and then presenting results. The possibility exists of creating a new bespoke algorithm from a description. Returning to the DisplayPort 1.2 specification, the text below shows the Pass/Fail criteria.
3.2.5 Pass/Fail Criteria
   Voltage Peak to Peak will fall in the range:
      Output Level 1:0.34≤Result≤0.46
      Output Level 2:0.51≤Result≤0.68
      Output Level 3:0.69≤Result≤0.92
      Output Level 4:1.02≤Result≤1.38
   Nominal Setting is 400, 600, 800 and 1200 m Volts peak-peak

This definition can also be supported in the instrument by being able to add the notion of pass/fail with an expression for a custom measurement.

The system described in this disclosure allows a test specification such as the one below to be either inserted as text directly into the program, or the system may allow the test specification to be converted into a simple No-Code prompt-friendly specification that can be executed directly.

For example, the below text shows a portion of a specification for one type of measurement in the DisplayPort 1.2 specification, which may include the sections 3.2.4 and 3.2.5 set out above. As discussed, taking the DisplayPort measurement definition, and converting the measurement definition to actions is achievable and can be done without writing a single line of code via the AI assistant.
3.2.1 Test Objective
To evaluate the waveform peak differential amplitude to ensure signal is neither over, nor under driven. (Reference: Table 3-10 VESA DisplayPort Standard)
3.2.2 Interoperability Statement
The source is given a range of expected output for each level setting that correlates with the system budget elements such as cable loss and receiver eye min and max values. This test ensures that the system budget is obeyed.
3.2.3 Test Conditions
Test shall be made on all Bit Rates supported without Pre-Emphasis for all differential voltage swings supported.
Test Pattern—PRBS 7

The AI assistant can take something like the full test specification for one type of measurement and convert the test specification to the necessary commands to perform the actions. The test and measurement system can do this conversion without requiring the user to write a single line of code. AI assistants tailored to test and measurement environments provide a high-level way to define what the user wants to accomplish rather than the detailed steps to accomplishing the user's goals If structured correctly, the resulting prompts to the AI assistants are instrument-, make-, and model-agnostic. Having test definitions that do not require porting when doing minor configuration changes is extremely valuable. AI assistants do not require the user to know details of programming T&M equipment. AI assistants may know what the users want to do, and that intent can be converted into action. AI assistants can define new measurements that do not yet exist. AI assistants can be used programmatically, which allows AI assistants to have the benefit be being easy to read and easy to write. AI assistants make debugging easier because if the user makes requests that the instruments cannot handle, the AI assistant returns appropriate messages, and then AI assistants can offer help in resolving the requests. AI assistants can be integrated into existing automation tools. AI assistants turn the process of writing a test from a coding exercise to a specification exercise. The resulting test definitions are easier to trace to requirements, are easier to write, are easier to review, and are easier to debug than some code environments.

Aspects of the disclosure may operate on particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a test and measurement system, comprising: one or more test and measurement instruments comprising at least one test and measurement instrument having one or more ports to connect the at least one test and measurement instrument to a device under test (DUT); one or more memories including test and measurement knowledge; a generative artificial intelligence (AI) model connected to the one or more test and measurement instruments, and the one or more memories; one or more processors configured to execute code that causes the one or more processors to: present a user interface having a prompt to a user of the one or more test and measurement instruments; receive a request from the user through the user interface, the request comprising one or more tasks to be performed by the one or more test and measurement instrument; access an application programming interface (API) of the generative AI model to translate the request to commands for the one or more test and measurement instruments; send the commands to the one or more test and measurement instruments; and display an output from the one or more test and measurement instruments on the user interface.

Example 2 is the test and measurement system of Example 1, wherein the one or more processors reside on one or more of the one or more test and measurement instruments, a computing device connected to the test and measurement instrument, a cloud server, and an edge server.

Example 3 is the test and measurement system of either of Examples 1 or 2, wherein the test and measurement knowledge includes one or more of general test and measurement information, information specific to the one or more test and measurement instruments, standards information, and package information.

Example 4 is the test and measurement system of any of Examples 1 through 3, wherein the code that causes the one or more processors to send the commands to the one or more test and measurement instruments comprises code that causes the one or more processors to: generate a list of functions to call with arguments for the functions; and send the functions and the commands to the one or more test and measurement instruments.

Example 5 is the test and measurement instrument of Example 4, wherein the one or more processors are further configured to execute code that causes the one or more processors to: receive a status of the functions from the one or more test and measurement instruments to allow the one or more processors to display results on the user interface.

Example 6 is the test and measurement system of any of Examples 1 through 5, wherein the one or more processors are further configured to execute code to cause the one or more processors to determine capabilities of the one or more test and measurement instruments.

Example 7 is the test and measurement system of any of Examples 1 through 6, wherein code that causes the one or more processors to send the commands to the one or more test and measurement instruments comprises code that causes the one or more processors to send commands to the one or more test and measurement instruments to cause the one or more test and measurement instruments to perform actions.

Example 8 is the test and measurement system of any of Examples 1 through 7, wherein code that causes the one or more processors to send the commands to the one or more test and measurement instruments comprises code that causes the one or more processors to send a query about status of execution of the commands to one or more test and measurement instruments.

Example 9 is the test and measurement system of any of Examples 1 through 8, wherein the code that causes the one or more processors to receive the request from the user through the user interface comprises code to cause the one or more processors to receive requests through a voice interface.

Example 10 is the test and measurement system of any of Examples 1 through 9, wherein the one or more processors are further configured to store the request and the commands for later access without using the generative AI model.

Example 11 is the test and measurement system of any of Examples 1 through 10, wherein the one or more processors are further configured to execute code to receive configuration information about the one or more test and instruments.

Example 12 is the test and measurement system of any of Examples 1 through 11, wherein the test and measurement knowledge includes primitives.

Example 13 is the test and measurement system of Example 12, wherein the one or more processors are further configured to execute code to cause the one or more processors to receive user input of one or more measurements, use primitives to create the one or more measurements, and store the user input as a custom measurement.

Example 14 is a computer-implemented method of creating an artificial intelligence (AI) assistant for test and measurement environments, comprising: accessing an application programming interface for a generative AI model; generating a list of functions to call with arguments for the functions; providing the list of functions to call and the arguments to the generative AI model; loading general test and measurement knowledge to the generative AI model; connect to one or more test and measurement instruments; creating a description for each of the one or more test and measurement instruments; and loading specific knowledge about the one or more test and measurement instruments to the generative AI model to create the AI assistant.

Example 15 is the computer-implemented method of Example 14, further comprising receiving a series of commands through a user interface of one test and measurement instrument of the one or more test and measurement instruments, the commands to cause the one test and measurement instrument to perform actions; generating a script comprising the series of commands; and storing the script for further use that does not require the AI assistant.

Example 16 is the computer-implemented method of either of Examples 14 or 15, further comprising: receiving make and model information for the one or more test and measurement instruments; and using the make and model information to allow the AI assistant to connect to the one or more test and measurement instruments directly.

Example 17 is the computer-implemented method of any of Examples 14 through 16, further comprising: receiving a test specification; and converting the test specification to a script.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific aspects of this disclosure have been illustrated and described for purposes of illustration, it will be understood that various modifications may be made without departing from the spirit and scope of the invention. Accordingly, the invention should not be limited except as by the appended claims.

1. A test and measurement system, comprising:
one or more test and measurement instruments comprising at least one test and measurement instrument having one or more ports to connect the at least one test and measurement instrument to a device under test (DUT);
one or more memories including test and measurement knowledge;
a generative artificial intelligence (AI) model connected to the one or more test and measurement instruments, and the one or more memories;
one or more processors configured to execute code that causes the one or more processors to:
present a user interface having a prompt to a user of the one or more test and measurement instruments;
receive a request from the user through the user interface, the request comprising one or more tasks to be performed by the one or more test and measurement instrument;
access an application programming interface (API) of the generative AI model to translate the request to commands for the one or more test and measurement instruments;
send the commands to the one or more test and measurement instruments; and
display an output from the one or more test and measurement instruments on the user interface.

2. The test and measurement system as claimed in claim 1, wherein the one or more processors reside on one or more of the one or more test and measurement instruments, a computing device connected to the test and measurement instrument, a cloud server, and an edge server.

3. The test and measurement system as claimed in claim 1, wherein the test and measurement knowledge includes one or more of general test and measurement information, information specific to the one or more test and measurement instruments, standards information, and package information.

4. The test and measurement system as claimed in claim 1, wherein the code that causes the one or more processors to send the commands to the one or more test and measurement instruments comprises code that causes the one or more processors to:
generate a list of functions to call with arguments for the functions; and
send the functions and the commands to the one or more test and measurement instruments.

5. The test and measurement instrument as claimed in claim 4, wherein the one or more processors are further configured to execute code that causes the one or more processors to:
receive a status of the functions from the one or more test and measurement instruments to allow the one or more processors to display results on the user interface.

6. The test and measurement system as claimed in claim 1, wherein the one or more processors are further configured to execute code to cause the one or more processors to determine capabilities of the one or more test and measurement instruments.

7. The test and measurement system as claimed in claim 1, wherein code that causes the one or more processors to send the commands to the one or more test and measurement instruments comprises code that causes the one or more processors to send commands to the one or more test and measurement instruments to cause the one or more test and measurement instruments to perform actions.

8. The test and measurement system as claimed in claim 1, wherein code that causes the one or more processors to send the commands to the one or more test and measurement instruments comprises code that causes the one or more processors to send a query about status of execution of the commands to one or more test and measurement instruments.

9. The test and measurement system as claimed in claim 1, wherein the code that causes the one or more processors to receive the request from the user through the user interface comprises code to cause the one or more processors to receive requests through a voice interface.

10. The test and measurement system as claimed in claim 1, wherein the one or more processors are further configured to store the request and the commands for later access without using the generative AI model.

11. The test and measurement system as claimed in claim 1, wherein the one or more processors are further configured to execute code to receive configuration information about the one or more test and instruments.

12. The test and measurement system as claimed in claim 1, wherein the test and measurement knowledge includes primitives.

13. The test and measurement system as claimed in claim 12, wherein the one or more processors are further configured to execute code to cause the one or more processors to receive user input of one or more measurements, use primitives to create the one or more measurements, and store the user input as a custom measurement.

14. A computer-implemented method of creating an artificial intelligence (AI) assistant for test and measurement environments, comprising:
accessing an application programming interface for a generative AI model;
generating a list of functions to call with arguments for the functions;
providing the list of functions to call and the arguments to the generative AI model;
loading general test and measurement knowledge to the generative AI model;
connect to one or more test and measurement instruments;
creating a description for each of the one or more test and measurement instruments; and
loading specific knowledge about the one or more test and measurement instruments to the generative AI model to create the AI assistant.

15. The computer-implemented method as claimed in claim 14, further comprising
receiving a series of commands through a user interface of one test and measurement instrument of the one or more test and measurement instruments, the commands to cause the one test and measurement instrument to perform actions;
generating a script comprising the series of commands; and
storing the script for further use that does not require the AI assistant.

16. The computer-implemented method as claimed in claim 14, further comprising:
receiving make and model information for the one or more test and measurement instruments; and
using the make and model information to allow the AI assistant to connect to the one or more test and measurement instruments directly.

17. The computer-implemented method as claimed in claim 14, further comprising:
receiving a test specification; and
converting the test specification to a script.
